(19) United States
(12) Patent Application Publication
(10) Pub. No.: US 2005/0066254 A1
(43) Pub. Date: Mar. 24, 2005

(54) Error detection in redundant array of storage units

(75) Inventors: Bernard John Grainger, Hampshire (GB); Robert Frank Maddock, Dorset (GB)

Correspondence Address: HARRINGTON & SMITH, LLP, 4 RESEARCH DRIVE, SHELTON, CT, 06484-6212, US

(73) Assignee: International Business Machines Corporation

(21) Appl. No.: 10/938,278

(22) Filed: Sep. 10, 2004

(30) Foreign Application Priority Data
Sep. 24, 2003 (GB) 0322424.3

(51) Int. Cl. G11C 29/00

(52) U.S. Cl. 714/764

(57) ABSTRACT

A storage controller (160) and method (200) for error detection in disk arrays (150) with multiple redundancy by: receiving from each of the disks in the array a linear XOR value derived from data in a desired segment of the unit; comparing the received values from the different disks; and determining, responsive to the comparison, an error in data from one of the disks. Scrubbing is completed by reconstructing, responsive to the error determination, the erroneous data and re-writing it to the erroneous segment. This allows detection of data errors where prior art could not, and detects these errors without a significant increase in controller-disk link data traffic.

### FIELD OF THE INVENTION

This invention relates to error detection in redundant storage systems.

### BACKGROUND OF THE INVENTION

In the field of this invention it is known to employ, typically periodically, data scrubbing (examining blocks of stored data and reconstructing data in any bad blocks found) in a RAID (Redundant Array of Independent Disks) array to maintain/improve the integrity of the array's stored data.

From patent publication no. WO 02/088922 A2 that data scrubbing may be performed on a storage array of multiple disk drives and controllers by reading data from within a data range from at least one of the disk drives, calculating a new Exclusive-OR (XOR) checksum for the data, comparing the new checksum with a pre-existing checksum for the data, and determining an error if the checksums are not equal.

However, this approach has the disadvantage(s) that it results in significant data traffic on a controller link.

A need therefore exists for scrubbing disk arrays with multiple redundancy wherein the abovementioned disadvantage(s) may be alleviated.

### STATEMENT OF INVENTION

In accordance with a first aspect of the present invention there is provided a storage controller for error detection in an array of a plurality of storage units, comprising: means for receiving from each of the units in the array a value derived from data in a desired segment of the unit; means for comparing the received values from the different units; and means, responsive to the means for comparing, for determining an error in data from one of the units.

Preferably, the value derived from data in a desired segment of the unit is a linear XOR logic combination of the data.

Preferably, the array is a multiply redundant array.

Preferably, the storage units comprise disk drives.

Preferably, the storage controller further comprises means, responsive to the means for determining an error, for reconstructing the erroneous data and for re-writing it to the erroneous segment.

In a second aspect of the present invention, there is provided a method of error detection in an array of a plurality of storage units, comprising: receiving from each of the units in the array a value derived from data in a desired segment of the unit; comparing the received values from the different units; and determining, responsive to the step of comparing, an error in data from one of the units.

Preferably, the value derived from data in a desired segment of the unit is a linear XOR logic combination of the data.

Preferably, the array is a multiply redundant array.

Preferably, the storage units comprise disk drives.

The method preferably further comprises reconstructing, responsive to the step of determining an error, the erroneous data and re-writing it to the erroneous segment.

The present invention may preferably be embodied as an integrated circuit comprising the storage controller of the first aspect.

The present invention may preferably be embodied as a storage controller, for error detection in an array of a plurality of storage units.

In its preferred embodiment this invention improves the background data scrub process for RAID storage systems, by improving data integrity without a significant increase in link data traffic.

### BRIEF DESCRIPTION OF THE DRAWINGS

One method and disk controller for scrubbing disk arrays with multiple redundancy incorporating the present invention will now be described, by way of example only, with reference to the accompanying drawings, in which:

FIG. 1 shows a block schematic diagram illustrating a data processing system including a storage system incorporating a RAID array and a disk array controller in accordance with the present invention; and

FIG. 2 shows a flow diagram illustrating a method of data scrubbing employed by the disk array controller of FIG. 1.

### DESCRIPTION OF PREFERRED EMBODIMENT

Disk arrays with single redundancy, such as RAID-5, can survive the failure of one disk without loss of data. However, if even one small part of one of the remaining disks cannot be read, some data will be lost. For this reason, it is common to ‘scrub’ the disks of a RAID-5 array. This entails reading all the data on every disk, so that any unreadable part can be found while the array is complete and the unreadable data can be re-created. It would be possible to read the data and corresponding parity from all the disks of the array and check that the parity matched the data. However, if a mismatch was found, there would be no way to tell which disk was incorrect, and so no correction could be made. For this reason it is normal only to check that the data can be read.

To avoid transferring the data from the disk to a storage controller, and thereby using bandwidth in the connection, the SCSI (Small Computer Systems Interface) standard for disk commands includes a VERIFY command which will confirm that the data can be read, but not transfer it to the controller.

To provide a higher level of data protection, it is possible to construct disk arrays with multiple redundancy, so that they can survive the loss or two of more disks. In these arrays, the data scrubbing can correct errors, since there are multiple ways to re-create any segment of data. If one check does not match, each segment involved can be checked against another disjoint set of segments to determine which segment is in error. This repair is clearly valuable, and is desirably implemented in any multiply redundant array.

However, if all the data segments from the disk are read into the controller, a lot of connection bandwidth will be used.

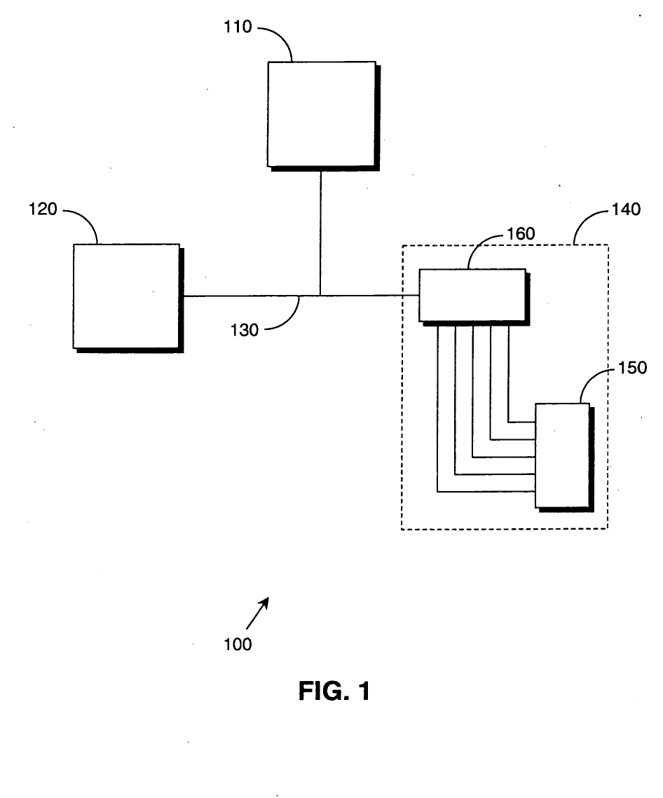

Referring now to FIG. 1, a data processing system 100 substantially avoids this use of bandwidth. The system 100 includes a processor 110 and system memory 120, both connected via a data bus 130 to a disk storage system 140. The disk storage system comprises a multiply-redundant disk storage array 150 (with multiple disks, not shown) and a storage array controller 160. As will be discussed in greater detail below, in order to allow disk scrubbing without significantly increasing controller link bandwidth, the storage array controller provides a new disk command, which reads a segment of data, and returns not the segment of data, but a single word which is the XOR of each word of data in that segment. These XOR values can be checked for corresponding segments on separate disks. If they match, there is a high probability that the full data matches. If they do not match, the full data can be read and it can be determined exactly where the error lies.

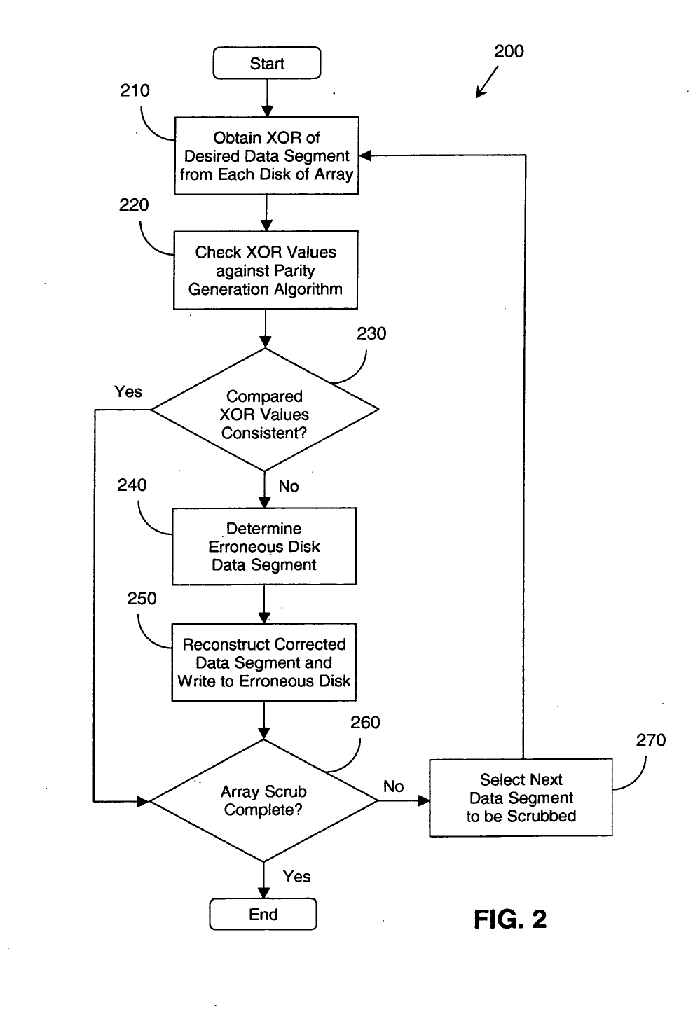

Referring now also to FIG. 2, the method 200 employed by the controller 160 to scrub the disk array 150 begins, at step 210, by obtaining linear XOR values for a desired data from each disk of the array 150. The XOR values are derived in the respective disk drives and the XOR values are transmitted to the controller 160, without the need for the data itself to be transferred to the controller which would require significant link bandwidth. At step 220, the obtained XOR values are checked for consistency with a parity generation algorithm. At step 230, if the compared XOR values are consistent, the method transfers to step 260 (as will be described below) to check whether the array scrub is complete. At step 240, if the compared values are inconsistent, the erroneous disk data segment giving rise to the inconsistency is determined. At step 250, the data for the erroneous segment is reconstructed using known techniques such as copying data from ‘good’ segments of other drives, and the reconstructed corrected data is written to the erroneous disk. At step 260, a check is made of whether scrubbing of the entire disk array is complete, and if so the method ends. If not, at step 270, the next data segment to be scrubbed is selected and the method returns to step 210.

It will be appreciated that for a single parity drive, checking for consistency of the XOR values with a parity generation algorithm can be achieved by XORing the XOR values together and checking that the result is zero, which can be done without hardware support, i.e., directly by the disk controller processor (not shown).

To see this, consider a system with 3 disks (A, B and C) and one parity drive (P). Each of the disks has N bytes per sector, where A1 is the first byte on disk A, etc . . . .

The linear XOR of a sector on the A drive is given by:
AP=A1+A2+A3 . . . AN (1)

The linear XOR of a sector on the B drive is given by:
BP=B1+B2+B3 . . . BN (2)

The linear XOR of a sector on the C drive is given by:
CP=C1+C2+C3 . . . CN (3)

The linear XOR of a sector on the P drive is given by:
PP=P1+P2+P3 . . . PN (4)
where “+” represents XOR.

Also,
P1=A1+B1+C1,P2=A2+B2+C2 . . . PN=AN+BN+CN (5)
because this is how the parity is stored on the parity drive.

Therefore, subsitituting (5) into (4) gives:
PP=(A1+B1+C1)+(A2+B2+C2)+ . . . (AN+BN+CN) (6)

Now computing AP+BP+CP+PP by adding (1), (2), (3) and (6) gives:

$$\begin{matrix}AP + BP + CP + PP = ( A1 + B1 + C1 ) + ( A1 + B1 + C1 ) + \\ ( A2 + B2 + C2 ) + \\ ( A2 + B2 + C2 ) … ( AN + BN + CN ) + \\ ( AN + BN + CN ) \\ = 0 QED\end{matrix}$$

It will be understood that the disk controller 160 will typically be implemented in the form of an integrated circuit (not shown).

It will be appreciated that although the above example uses a linear XOR logical combination for each compared value, other types of associative logical combination may alternatively be used.

It will further be appreciated that this approach can still be of value in the case of an array with a single parity drive (such as RAID-3, RAID-4 or, most commonly, RAID-5), as it is clearly still useful to know that the data and its parity have become inconsistent. The error can be logged, and a user may still be able to recover data from a backup.

It will further be appreciated that although the above example has been described in the context of disk drives, it could alternatively be applied to an array of other kinds of storage units.

In summary, it will be understood that the above preferred embodiment provides a way of detecting and correcting “write mis-compares”, where a drive claims to have performed a write of data but in fact has not. The embodiment provides a way of implementing the ‘detection’ step without consuming significant bandwidth on the link between disks and storage controller.

In conclusion, it will be understood that the above-described scheme for scrubbing disk arrays with multiple redundancy described above provides the following advantages:
detects data errors where prior art could not—prior art assumes either that verifies are sufficient (not true if the parity has become inconsistent with the data) or reads all data segments during data-scrub with a considerable cost in connection bandwidth.
detect these errors without a significant increase in link data traffic.

1. A storage controller for error detection in an array of a plurality of storage units, comprising:
a receiving unit to receive from a plurality of the storage units in the array a value derived from data in a desired segment of the storage unit;
a comparing unit to compare the received values from different storage units; and
an error determining unit, responsive to the comparing unit, to determine an error in data from one of the storage units.

2. The storage controller of claim 1 wherein the value derived from data in a desired segment of the storage unit is a linear XOR logic combination of the data.

3. The storage controller of claim 1 wherein the array is a multiply redundant array.

4. The storage controller of claim 1 wherein the storage units comprise disk drives.

5. The storage controller of claim 1 further comprising a reconstruction unit, responsive to the error determining unit, to reconstruct erroneous data and to re-write the reconstructed erroneous data to an erroneous segment.

6. A method of error detection in an array of a plurality of storage units, comprising:
receiving from a plurality of the units in the array a value derived from data in a desired segment of the unit;
comparing the received values from the different units; and
determining, responsive to the step of comparing, an error in data from one of the units.

7. The method of claim 6 wherein the value derived from data in a desired segment of the unit is a linear XOR logic combination of the data.

8. The method of claim 6 wherein the array is a multiply redundant array.

9. The method of claim 6 wherein the storage units comprise disk drives.

10. The method of claim 6 further comprising reconstructing, responsive to the step of determining an error, the erroneous data and re-writing it to the erroneous segment.

11. An integrated circuit comprising the storage controller of claim 1.

12. A storage controller for error detection in an array of a plurality of storage units, comprising:
means for receiving from a plurality of the units in the array a value derived from data in a desired segment of the unit;
means for comparing the received values from the different units; and
means, responsive to the means for comparing, for determining an error in data from one of the units.

13. The storage controller of claim 12 wherein the value derived from data in a desired segment of the unit is a linear XOR logic combination of the data.

14. The storage controller of claim 12 wherein the array is a multiply redundant array.

15. The storage controller of claim 12 wherein the storage units comprise disk drives.

16. The storage controller of claim 12 further comprising means, responsive to the means for determining an error, for reconstructing the erroneous data and for re-writing it to the erroneous segment.

17. A signal bearing medium tangibly embodying a program of machine-readable instructions executable by a digital processing apparatus to perform operations to detect data errors in a redundant storage system comprised of an array of storage units, the operations comprising:
receiving from a plurality of the storage units in the array a value derived from data in a desired segment of the storage unit;
comparing the received values from different storage units; and
determining, responsive to comparing, an error in data from one of the storage units.

18. A signal bearing medium as in claim 17, where the value derived from data in a desired segment of the storage unit is a linear XOR logic combination of the data.

19. A signal bearing medium as in claim 17, where the array is comprised of a multiply redundant array of disk drives.

20. A signal bearing medium as in claim 17, further comprising reconstructing, responsive to determining an error, the erroneous data and re-writing it to an erroneous segment.

21. A disk controller coupled to at least one controlled disk, comprising circuitry coupled to an external data processor via a bus, said circuitry responsive to a receipt over the bus of a predetermined type of read command to read a specified segment of data from the at least one controlled disk, to determine a value of an Exclusive OR operation performed on data read from the specified segment, and to return to said external data processor over said bus the determined value.

22. A storage array controller coupled to at least one disk controller that is coupled to a plurality of controlled disks, said storage array controller comprising circuitry, coupled to said at least one disk controller via a bus, to issue a predetermined type of read command over the bus to the at least one disk controller to read a specified segment of data from the plurality of controlled disks, said at least one disk controller comprising circuitry responsive to a receipt of the read command to determine a value of an associate logical combination operation performed on data read from the specified segment on each of the plurality of controlled disks and to return a plurality of said determined values to said storage array controller over said bus, said storage array controller circuitry further being responsive to a receipt of said plurality of returned determined values to determine if the plurality of returned determined values are consistent and, if they are determined to be inconsistent, to initiate a data reconstruction operation for a segment determined to be a cause of the inconsistency.

23. A storage array controller as in claim 22, where the associate logical combination operation is comprised of a linear Exclusive OR operation performed on bytes read from the specified segment.

24. A storage array controller as in claim 22, where at least one of the controlled disks comprises a part of a parity disk drive.

25. A storage array controller as in claim 22, comprising a part of a RAID data storage system.
